(19) United States
(12) Patent Application Publication
(10) Pub. No.: US 2025/0316494 A1
(43) Pub. Date: Oct. 9, 2025

(54) TECHNIQUES FOR SURFACE MODIFICATIONS DURING BONDING PROCEDURES

(71) Applicant: Micron Technology, Inc., Boise, ID (US)

(72) Inventors: Andrew M. Bayless, Boise, ID (US); Jeremy Minnich, Boise, ID (US)

(21) Appl. No.: 19/087,216

(22) Filed: Mar. 21, 2025

Related U.S. Application Data
(60) Provisional application No. 63/574,494, filed on Apr. 4, 2024.

(51) Int. Cl. H01L 21/311; B23K 20/02; B23K 101/40; H01L 21/3105; H01L 23/00; H10B 80/00

(52) U.S. Cl. CPC H01L 21/31144; B23K 20/02; H01L 21/31053; H01L 24/83; H10B 80/00; B23K 2101/40; H01L 2224/83201

(57) ABSTRACT

Methods, systems, and devices for surface modifications during bonding procedures are described. A memory device may be manufactured by polishing a first semiconductor and a second semiconductor, where the first semiconductor has a first surface and a second surface, and the second semiconductor has a third surface and a fourth surface. The first surface and the third surface may be polished to have a first roughness. Accordingly, a portion of the first surface may be etched according to a pattern, where the portion of the first surface has a second roughness that is different than the first roughness. Similarly, a portion of the third surface may be etched according to a second pattern, where the portion of the third surface has the second roughness. Based on etching the first surface and the third surface, the first surface and the third surface may be bonded.

### CROSS REFERENCE

The present Application for Patent claims priority to U.S. Patent Application No. 63/574,494 by Bayless et al., entitled “TECHNIQUES FOR SURFACE MODIFICATIONS DURING BONDING PROCEDURES,” filed Apr. 4, 2024, which is assigned to the assignee hereof, and which is expressly incorporated by reference in its entirety herein.

### TECHNICAL FIELD

The following relates to one or more systems for memory, including techniques for surface modifications during bonding procedures.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells. In some cases, memory devices may be manufactured by bonding two semiconductors, such as wafers or dies, together.

### BRIEF DESCRIPTION OF THE DRAWINGS

FIG. 1 shows an example of a system that supports techniques for surface modifications during bonding procedures in accordance with examples as disclosed herein.

FIG. 2A shows an example of a bonding process that supports techniques for surface modifications during bonding procedures in accordance with examples as disclosed herein.

FIG. 2B shows an example of a roughness diagram that supports techniques for surface modifications during bonding procedures in accordance with examples as disclosed herein.

FIG. 3A shows an example of a processing step that supports techniques for surface modifications during bonding procedures in accordance with examples as disclosed herein.

FIG. 3B shows an example of a processing step that supports techniques for surface modifications during bonding procedures in accordance with examples as disclosed herein.

FIG. 4A shows an example of a processing step that supports techniques for surface modifications during bonding procedures in accordance with examples as disclosed herein.

FIG. 4B shows an example of a processing step that supports techniques for surface modifications during bonding procedures in accordance with examples as disclosed herein.

FIG. 4C shows an example of a processing step that supports techniques for surface modifications during bonding procedures in accordance with examples as disclosed herein.

FIG. 5A shows an example of a processing step that supports techniques for surface modifications during bonding procedures in accordance with examples as disclosed herein.

FIG. 5B shows an example of a processing step that supports techniques for surface modifications during bonding procedures in accordance with examples as disclosed herein.

FIG. 5C shows an example of a processing step that supports techniques for surface modifications during bonding procedures in accordance with examples as disclosed herein.

FIG. 6 shows a flowchart illustrating a method or methods that support techniques for surface modifications during bonding procedures in accordance with examples as disclosed herein.

### DETAILED DESCRIPTION

Some memory devices may be manufactured by bonding multiple semiconductors (e.g., wafers or memory dies), where such semiconductors may include one or more components of the memory devices. For example, a first semiconductor (e.g., a first wafer or a first die), having a first surface and a second surface, may have a dielectric film applied to the first surface, while a second semiconductor (e.g., a second wafer or a second die), having a third surface and a fourth surface, may have the dielectric material applied to the third surface. Based on applying the dielectric material, the first surface of the first semiconductor device and the third surface of the second semiconductor device may be polished, such as by a chemical mechanical polishing (CMP) procedure, and subsequently cleaned. Based on polishing and cleaning the first surface and the third surface, the first surface of the first semiconductor and the third surface of the second semiconductor may be positioned (e.g., aligned) over one another and bonded together.

To bond the first surface and the third surface, a pressure (e.g., via a pin) may be applied to the center of the second surface of the first semiconductor device, to the fourth surface of the second semiconductor device, or both, where such pressure may cause one or more segments extending from the center of the first surface and the third surface to couple together. Such coupling of the segments of the first surface and the third surface may be referred to as a bond wave. In order to achieve an aligned bonding between the first surface and the third surface (e.g., the first semiconductor and the second semiconductor are aligned perfectly), a radial bond wave may be desired. However, due to various factors during the bonding procedure, an undesirable bond wave (e.g., a square or an asymmetrical bond wave) may occur, leading to a misalignment between the two semiconductors. For example, stresses (e.g., deformities) in the semiconductors, layouts of the components on the semiconductors, settings on the tools used to bond the two semiconductors, a roughness of the first surface and the third surface of the two semiconductors, or a combination thereof, may cause an undesirable bond wave, leading to misalignment. Thus, techniques may be desired to achieve a radial bond wave during the bonding process.

According to the techniques described herein, portions of the first surface, portions of the third surface, or both may be roughened (e.g., altered) prior to bonding, such that a velocity of the bond wave over the roughened portions may be decreased relative to unroughened portions of the first surface and the third surface (e.g., slow the velocity of the coupling between the first surface and the third surface over the roughened portions), thereby achieving a radial bond wave. For example, in response to the polishing, the first surface and the third surface may have a first roughness (e.g., 0.2-0.25 nanometer (nm) average roughness (RA)). Based on the polishing, a portion of the first surface may be etched according to a first pattern (e.g., a star pattern, a radial pattern, a combination of radial and star pattern, an asymmetrical pattern, or the like), such that the portion of the first surface has a second roughness (e.g., 0.3-0.5 nm RA) different from the first roughness. Similarly, a portion of the third surface may be etched according to a second pattern, such that the portion of the third surface has the second roughness. In such examples, the first and second patterns may be selected based on the characteristics (e.g., stresses, layouts, or both) of the semiconductors, such that a radial bond wave may be achieved during the bonding of the first surface and the third surface. In this way, by intentionally roughening the first surface and the third surface according to an identified pattern, the velocity of the bond wave may be controlled, thereby producing a radial bond wave and preventing misalignments between the first semiconductor and the second semiconductor.

In addition to applicability in memory systems as described herein, techniques for surface modification during bonding procedures may be generally implemented to improve the sustainability of various electronic devices and systems. As the use of electronic devices has become even more widespread, the quantity of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by reducing materials used in production of electronic devices and eliminating production processes, which may result reduced electronic waste, among other benefits.

Features of the disclosure are illustrated and described in the context of systems and architectures. Features of the disclosure are further illustrated and described in the context of bond waves, roughness diagrams, processing steps, and flowcharts.

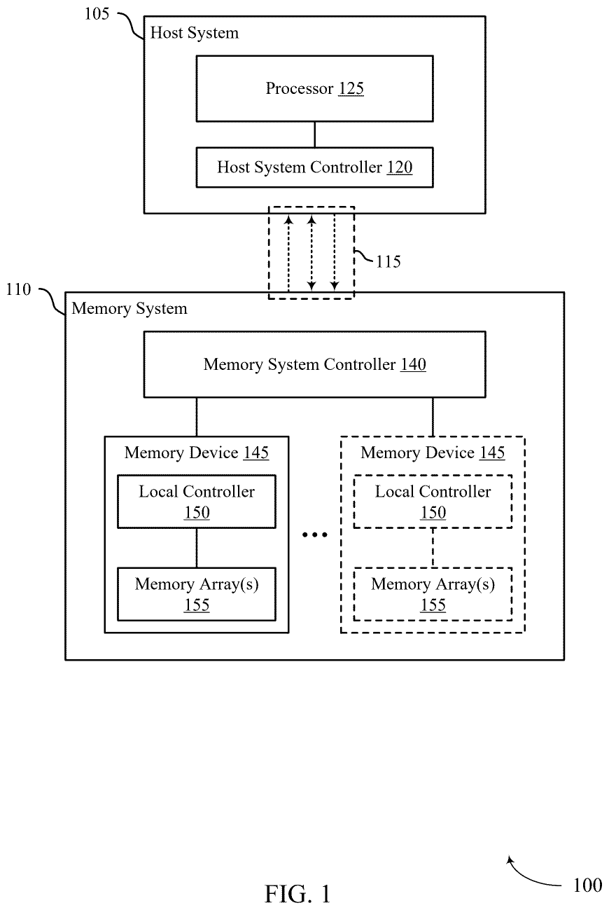

FIG. 1 illustrates an example of a system 100 that supports techniques for surface modifications during bonding procedures in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

Some memory devices 145, memory systems 110, or host systems 105 may be manufactured by bonding multiple semiconductors (e.g., wafers or memory dies), where such semiconductors may include one or more components of the memory devices 145, the memory systems 110, or the host systems 105. For example, a first semiconductor (e.g., a first wafer or a first die), having a first surface and a second surface, may have a dielectric film applied to the first surface, while a second semiconductor (e.g., a second wafer or a second die), having a third surface and a fourth surface, may have the dielectric material applied to the third surface. Based on applying the dielectric material, the first surface of the first semiconductor device and the third surface of the second semiconductor device may be polished and subsequently cleaned. Based on polishing and cleaning the first surface and the third surface, the first surface of the first semiconductor and the third surface of the second semiconductor may be positioned (e.g., aligned) over one another and bonded together.

To bond the first surface and the third surface, a pressure (e.g., via a pin) may be applied to the center of the second surface of the first semiconductor device, to the fourth surface of the second semiconductor device, or both, where such pressure may cause one or more segments extending from the center of the first surface and the third surface to couple together. Such coupling of the segments of the first surface and the third surface may be referred to as a bond wave. In order to achieve an aligned bonding between the first surface and the third surface (e.g., the first semiconductor and the second semiconductor are aligned perfectly), a radial bond wave may be desired. However, due to various factors during the bonding procedure, an undesirable bond wave (e.g., a square or an asymmetrical bond wave) may occur, leading to a misalignment between the two semiconductors. For example, stresses (e.g., deformities) in the semiconductors, layouts of the components on the semiconductors, settings on the tools used to bond the two semiconductors, a roughness of the first surface and the third surface of the two semiconductors, or a combination thereof, may cause an undesirable bond wave, leading to misalignment. Thus, techniques may be desired to achieve a radial bond wave during the bonding process.

According to the techniques described herein, portions of the first surface, portions of the third surface, or both may be roughened (e.g., altered) prior to bonding, such that a velocity of the bond wave over the roughened portions may be decreased relative to unroughened portions of the first surface and the third surface (e.g., slow the velocity of the coupling between the first surface and the third surface over the roughened portions), thereby achieving a radial bond wave. For example, in response to the polishing, the first surface and the third surface may have a first roughness (e.g., 0.2-0.25 nm RA). Based on the polishing, a portion of the first surface may be etched according to a first pattern (e.g., a star pattern, a radial pattern, a combination of radial and star pattern, an asymmetrical pattern, or the like), such that the portion of the first surface has a second roughness (e.g., 0.3-0.5 nm RA) different from the first roughness. Similarly, a portion of the third surface may be etched according to a second pattern, such that the portion of the third surface has the second roughness. In such examples, the first and second patterns may be selected based on the characteristics (e.g., stresses, layouts, or both) of the semiconductors, such that a radial bond wave may be achieved during the bonding of the first surface and the third surface. In this way, by intentionally roughening the first surface and the third surface according to an identified pattern, a radial bond wave may be achieved, thereby preventing misalignments between the first semiconductor and the second semiconductor.

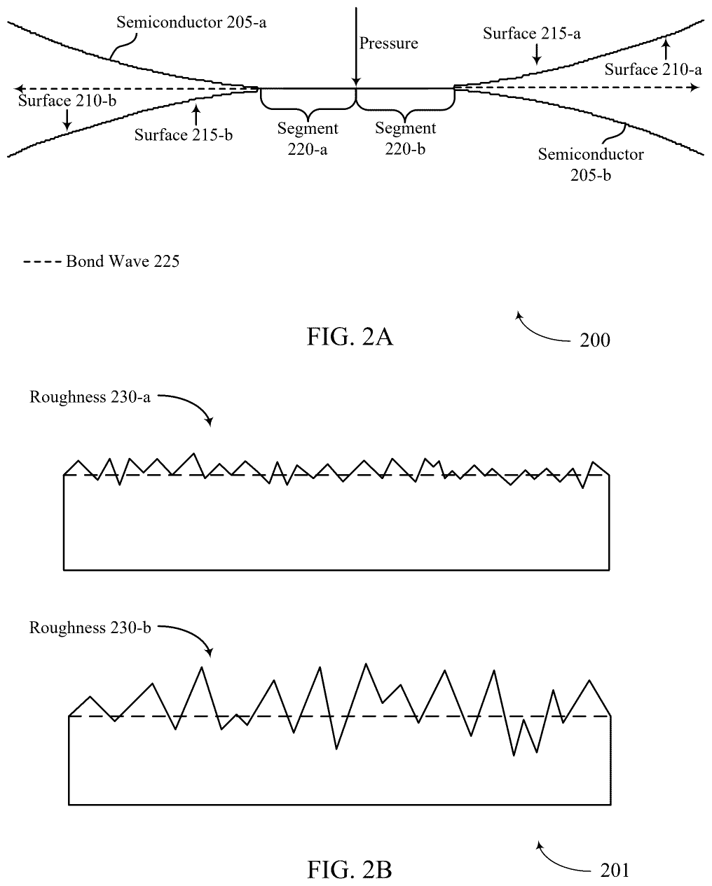

FIG. 2A and FIG. 2B show examples of a bonding process 200 and a roughness diagram 201, respectively, that support techniques for surface modifications during bonding procedures in accordance with examples as disclosed herein. Aspects of the bonding process 200 and the roughness diagram 201 may be implemented by the system 100. For example, aspects of the bonding process 200 and the roughness diagram 201 may be utilized to manufacture one or more memory devices 145, the memory system 110, the host system 105, or a combination thereof.

The techniques described within the context of the bonding process 200 of FIG. 2A may enable a semiconductor 205-a (e.g., a first semiconductor) and a semiconductor 205-b (e.g., a second semiconductor) to be bonded (e.g., coupled) together. The semiconductor 205-a may include a surface 210-a (e.g., a first surface or an inner surface) and a surface 215-a (e.g., a second surface or an outer surface), while the semiconductor 205-b may include a surface 210-b (e.g., a third surface or an inner surface) and a surface 215-b (e.g., a fourth surface or an outer surface). As described herein, the semiconductors 205 may be examples of wafers (e.g., device wafers, carrier wafers, or both), memory dies, or a combination of both. For example, the semiconductor 205-a and the semiconductor 205-b may both be wafers, where such wafers include one or more components (e.g., memory cells, control circuitry, access circuitry, or the like). In such examples, the semiconductor 205-a (e.g., first wafer) may be bonded with the semiconductor 205-b (e.g., second wafer) according to a wafer-to-wafer bond. As an illustrative example, the semiconductor 205-a may be a device wafer (e.g., a wafer carrying various components that construct, or are a part of, memory dies or devices) and the semiconductor 205-b may be a carrier wafer (e.g., a wafer used as structural support for device wafers). Accordingly, the semiconductor 205-a may be bonded with the semiconductor 205-b as part of a device wafer to carrier wafer bond. Alternatively, the semiconductor 205-a and the semiconductor 205-b may both be memory dies. In such examples, the semiconductor 205-a (e.g., first memory die) may be bonded with the semiconductor 205-b (e.g., second memory die) according to a die-to-die bond. In some examples, the semiconductor 205-a may be a wafer, while the semiconductor 205-b may be a memory die. In such examples, the semiconductor 205-a may be bonded with the semiconductor 205-b according to a die-to-wafer bond.

In some examples, a fusion bonding technique may be used to bond the surface 210-a with the surface 210-b. In fusion bonding, a dielectric material (e.g., oxide) may be applied to the surface 210-a and the surface 210-b. Based on applying the dielectric material, the surface 210-a and the surface 210-b may be polished, such as according to a CMP procedure, and subsequently cleaned. Based on cleaning the surfaces 210 (e.g., inner surfaces), the surface 210-a may be positioned over the surface 210-b. To bond the surface 210-a and the surface 210-b, a pressure may be applied to the center of the surface 215-a (e.g., or the surface 215-b), where such pressure may cause one or more segments 220 (e.g., the segment 220-a and the segment 220-b) extending from the center of the surfaces 210 to couple together (e.g., bond together). For example, based on applying the pressure, the dielectric material on the surface 210-a and the surface 210-b may attract, causing the surface 210-a and the surface 210-b to couple together. Such coupling of the segments 220 of the surfaces 210 may cause the adjacent segments of the surfaces to be closer together. The increased proximity of the surfaces may cause those adjacent segments to then couple. Such a cascading process of coupling may create something that may be referred to as a bond wave 225. In some examples, the manufacturing procedure may utilize a hybrid bonding technique, which may include a fusion bond between the surface 210-a and the surface 210-b and also include a bond between one or more copper pads formed on the surface 210-a and the surface 210-b.

However, some fusion and hybrid bond alignments may be limited by manufacturing equipment (e.g., control equipment). For example, in order to achieve an aligned bonding between the surface 210-a and the surface 210-b (e.g., the semiconductor 205-a and the semiconductor 205-b are), a radial bond wave 225 may be desired. Such a radial bond wave 225 may have a same velocity (e.g., same coupling speed of the segments 220 radiating away from the initial pressure point) in each direction while bonding the surfaces 210. However, due to stresses (e.g., deformities) in the semiconductors 205, layouts of the components on the semiconductors 205, settings on the tools used to bond the two semiconductors 205 (e.g., vacuum settings), a roughness 230 of the surfaces 210, or a combination thereof, a velocity of the bond wave 225 may vary in different directions during the bonding, thereby causing undesirable bond wave 225 (e.g., square bond wave) and leading to misalignment between the semiconductors 205. That is, due to one or more characteristics of the semiconductor 205-a and the semiconductor 205-b, a square bond wave 225 may form, resulting in a misaligned bond between the semiconductor 205-a and the semiconductor 205-b. Thus, techniques may be desired to achieve a radial bond wave 225 during the bonding process.

With reference to the roughness diagram 201 of FIG. 2B and according to the techniques described herein, a manufacturing process may utilize bond surface engineering to create a constant velocity of the bond wave 225 in each direction, thereby minimizing distortion and preventing misalignment. For example, portions of the surface 210-a, the surface 210-b, or both (e.g., bond surfaces) may be roughened (e.g., altered) according to one or more patterns, thereby creating a different roughness 230 on the portions of the surfaces 210. Roughening the portions of the surfaces 210 may control the velocity of the bond wave 225. For example, a bond wave 225 between surfaces 210 with a roughness 230-a (e.g., 0.2-0.25 nm RA) may have an increased velocity relative to a bond wave 225 between surfaces 210 with a roughness 230-b (e.g., 0.3-0.5 nm RA). The roughness 230-a may be considered a smooth roughness, where the RA of the surface may be less than a threshold roughness, while the roughness 230-b may be considered an increased roughness, where the RA of the roughness 230-b be greater than the threshold roughness.

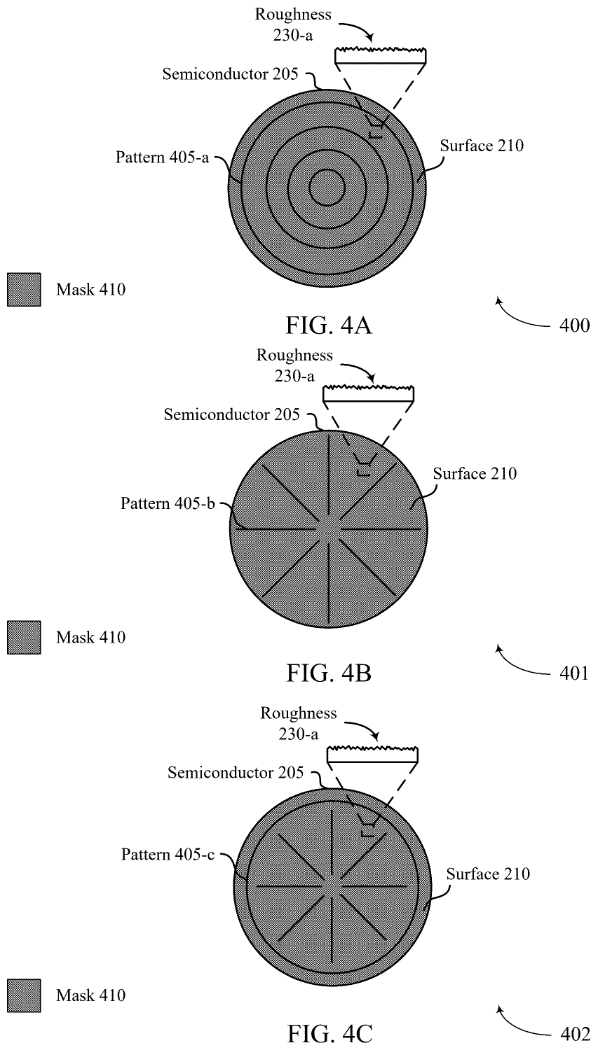

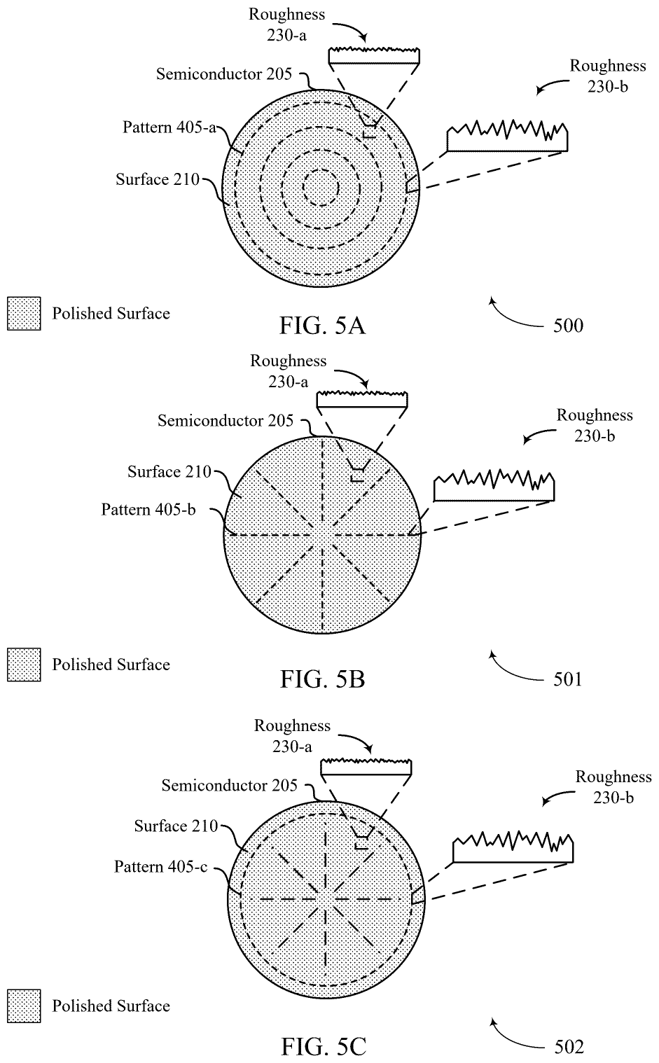

Accordingly, during the manufacturing process, a pattern may be selected for each surface 210 based on the characteristics (e.g., stresses, layouts, or both) of the surfaces 210, such that the bond wave 225 may be constant during the bonding process leading to a radial bond wave 225. Techniques to select the patterns and roughen the surfaces 210 of the semiconductors 205 may be further described herein with reference to FIGS. 4A through 5C. In some examples, material in the streets or on the surfaces 210 of the semiconductors may also be filled with alternate materials in order to control the velocity of the bond wave 225 (e.g., the shape of the bond wave 225).

By having a different roughness 230 on portions of the surfaces 210, the bond wave 225 may be altered to have a relatively decreased amount of distortion and impact from the manufacturing equipment. Further, by altering outside edges of the surfaces 210, the velocity of the bond wave 225 may be controlled at such outside edges, thereby preventing voiding. As such, the roughening of the surfaces 210 may reduce reliance on precision equipment during the bonding process, may be tailored to each semiconductor 205 (based on the characteristics of the semiconductor 205) to create a constant velocity of the bond wave 225, and enable better edge control to reduce voiding.

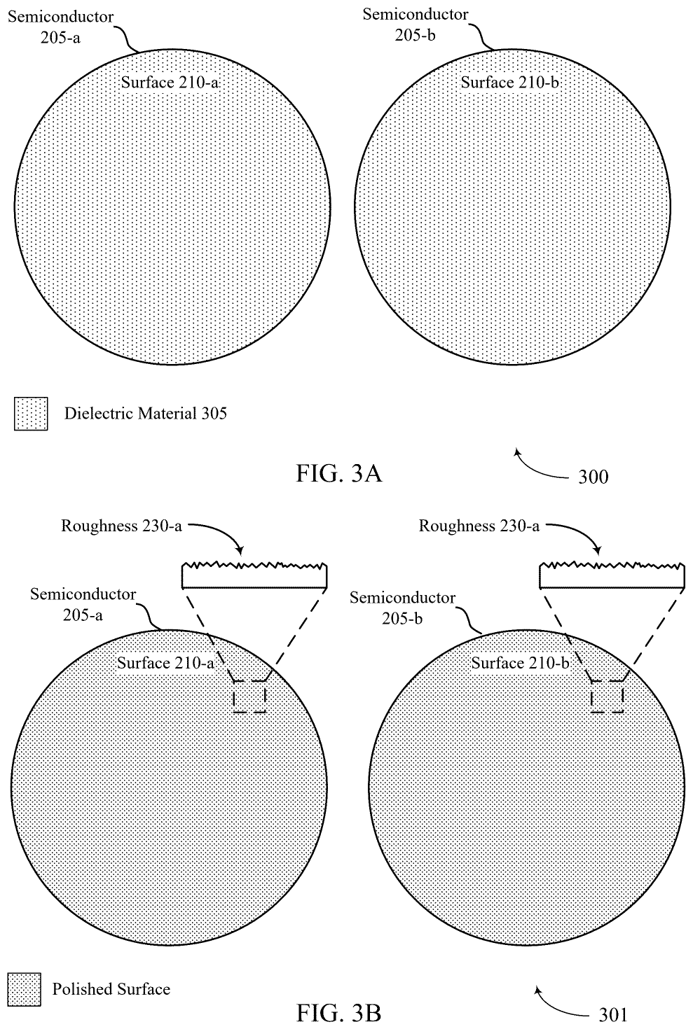

As an illustrative example, the semiconductor 205-a and the semiconductor 205-b may be examples of wafers, where each wafer may be formed to include respective components associated with multiple memory dies. For example, the semiconductor 205-a (e.g., wafer) may be formed to include a set of first components associated with memory dies, while the semiconductor 205-b (e.g., wafer) may be formed to include a set of second components associated with memory dies, where the connection between a first component and a second component may form a memory die. In response to forming the semiconductors 205 (e.g., wafers), the respective surfaces 210 of the semiconductors 205 may be patterned according to the techniques further described herein with reference to FIGS. 3-5C. In response to the patterning, the surface 210-a of the semiconductor 205-a may be bonded with the surface 210-b of the semiconductor 205-a by applying the pressure as described herein.

In such examples, the bonding between the semiconductor 205-a and the semiconductor 205-b (e.g., the wafer to wafer bond) may form multiple memory dies (e.g., by combining the respective sets of components included on each wafer together). In response to forming the multiple memory dies (e.g., bonding the two semiconductors 205), each memory die may be diced (e.g., singulated or separated) to form single memory dies, where each memory die includes a respective first component and a respective second component. In such examples, a bond line (e.g., connection) between the first component and the second component of each memory die may include (e.g., show) various roughness's 230 based on the patterning of the semiconductors 205. For example, a bond line of a memory die formed by the aforementioned process may include a first segment 220 having the roughness 230-a and include a second segment 220 having the roughness 230-b. That is, a memory die (e.g., memory device) formed by the aforementioned process may have a bond line (e.g., a connection between two components of the memory die), where a first segment 220 of the bond line may have the roughness 230-a and a second segment 220 of the bond line may have the roughness 230-b.

FIG. 3A and 3B show examples of a processing step 300 and a processing step 301, respectively, that support techniques for surface modifications during bonding procedures in accordance with examples as disclosed herein. Aspects of the processing step 300 and the processing step 301 may be implemented by a process that manufactures the memory devices 145, the memory system 110, the host system 105, or a combination thereof.

With reference to the processing step 300, prior to bonding, a dielectric material 305 may be applied to the surface 210-a of the semiconductor 205-a and to the surface 210-b of the semiconductor 205-b. In such examples, the dielectric material 305 may be an example of an oxide material, a silicon oxide (SiCN) material, a titanium oxide (TiOS) material, or the like. In some examples, a same dielectric material 305 may be applied to the surface 210-a and the surface 210-b. Alternatively, different dielectric materials 305 may be applied to the surfaces 210, for example, a first dielectric material 305 may be applied to the surface 210-a and a second dielectric material 305 may be applied to the surface 210-b. With reference to the processing step 301, the surface 210-a and the surface 210-b may be polished, such that the surface 210-a and the surface 210-b have a roughness 230-a. Such polishing may be performed as part of a CMP procedure.

FIG. 4A, FIG. 4B, and FIG. 4C show examples of a processing step 400, a processing step 401, and a processing step 402, respectively, that support techniques for surface modifications during bonding procedures in accordance with examples as disclosed herein. Aspects of the processing step 400, the processing step 401, and the processing step 402 may be implemented by a process that manufactures the memory devices 145, the memory system 110, the host system 105, or a combination thereof. Further, the processing step 400, the processing step 401, and the processing step 402 may be performed in response to the processing step 301 (e.g., polishing of the surfaces 210).

For example, respective patterns 405 may be selected for the surfaces 210, where such a selection may be based on the characteristics of the surfaces 210. For example, the surface 210-a may have a first set of characteristics, such as a first stress level, a first layout, or both, while the surface 210-b may have a second set of characteristics, such as a second stress level, a second layout, or both. Based on the first set of characteristics and the second set of characteristics, one or more patterns 405 may be selected for the surface 210-a and the surface 210-b in order to produce a radial bond wave 225.

In such examples, a same pattern 405 may be selected for both the surfaces 210. Alternatively, a different pattern 405 may be selected for the surfaces 210 (e.g., a first pattern 405 for the surface 210-a and a second pattern 405 for the surface 210-b). In some examples, a pattern 405 may be selected for the surface 210-a, while a pattern 405 may not be selected for the surface 210-b (e.g., a single surface 210 is roughened). In some examples, testing may be performed on the surfaces 210 in order to identify a pattern 405 that achieves a constant velocity of the bond wave 225 (e.g., a radial bond wave 225).

Based on selecting the patterns 405, a mask 410 (e.g., masking material) may be applied to the surfaces 210 according to the selected patterns, where such masking may prevent surface modification over the remaining portions of the surfaces 210 (e.g., unpatterned portions). For example, the mask 410 may be deposited according to the selected pattern 405, where the mask 410 may cover the surfaces 210 except for the portions of the surfaces 210 corresponding to the patterns 405 (e.g., except for the portions corresponding to areas that are to be roughened). In some examples, if a low-power laser etching procedure is used to roughen the patterned portions of the surfaces 210 to the roughness 230-b, the mask 410 may not be applied to the surfaces 210.

As described herein, one or more patterns 405 may be selected to control the velocity of the bond wave 225. For example, the patterns 405 may be symmetrical patterns, asymmetrical patterns, triangular patterns (not shown), square patterns (not shown), or a combination thereof. Additionally, with reference the processing step 400 of FIG. 4A, a mask 410 may be applied to the surfaces 210 according to a pattern 405-a, which may be referred to as a radial pattern. With reference to the processing step 401 of FIG. 4B, the mask 410 may be applied to the surfaces 210 according to a pattern 405-b, which may be referred to as a star pattern. In some examples, with reference to the processing step 402 of FIG. 4C, the mask 410 may be applied to the surfaces 210 according to a pattern 405-c, which may be referred to as a combination of a star pattern and a radial pattern. Although various patterns 405 have been illustrated and described, such patterns 405 are not an exhaustive list of patterns 405 that may be selected. That is, the techniques described herein may be utilized according to any pattern 405.

FIG. 5A, FIG. 5B, and FIG. 5C show examples of a processing step 500, a processing step 501, and processing step 502, respectively that support techniques for surface modifications during bonding procedures in accordance with examples as disclosed herein. Aspects of the processing step 500, the processing step 501, and the processing step 502 may be implemented by a process that manufactures the memory devices 145, the memory system 110, the host system 105, or a combination thereof. Further, the processing step 500, the processing step 501, and the processing step 502 may be performed in response to the processing steps 400, 401, and 402 (e.g., selecting a pattern 405 and applying the mask 410 to the surfaces 210 according to the pattern 405).

For example, based on applying the mask 410 to the surfaces 210 according to the selected patterns 405, portions of the surfaces 210 may be etched according to the patterns 405. In some examples, a plasma etching procedure may be performed to roughen the patterned portions of the surfaces 210 to the roughness 230-b, where, during the plasma etching procedure, plasma may be sent through to the patterned portions of the surfaces 210. Such plasma may be an argon plasma or a nitrogen plasma. In some other examples, a wet etching procedure may be performed to roughen the patterned portions of the surfaces 210 to the roughness 230-b. In some examples, a sand blasting procedure may be performed to roughen the patterned portions of the surfaces 210 to the roughness 230-b,where, during the sand blasting procedure, sand may be sent through to the patterned portions of the surfaces 210, thereby roughening the patterned portions of the surfaces 210 to the roughness 230-b.

In some examples, an ice blasting procedure may be performed to roughen the surfaces 210 to the roughness 230-b, where, during the ice blasting procedure, ice shavings may be sent through to the patterned portions of the surfaces 210, thereby roughening the patterned portions of the surfaces 210 to the roughness 230-b. In some examples, an implanting procedure may be performed to roughen the patterned portions of the surfaces 210 to the roughness 230-b. As described herein, a low-power laser etching procedure may be performed to roughen the patterned portions of the surfaces 210 to the roughness 230-b. In such examples, if the low-power laser etching procedure is performed, the mask 410 may not be applied to the surfaces 210 (e.g., the processing steps 400, 401, and 402 may not be performed).

Based on etching the patterned portions of the surfaces 210 to the roughness 230-b, the mask 410 may be removed from the surfaces 210. In response to removing the mask 410, the surfaces 210 (e.g., the surface 210-a and the surface 210-b) may be cleaned and positioned (e.g., aligned) over one another in preparation for bonding.

As an illustrative example and with reference to the processing step 500, the portions of the surfaces 210 corresponding to the pattern 405-a (e.g., radial pattern) may be etched, such that the patterned portions of the surfaces 210 have the roughness 230-b and the unpatterned portions of the surfaces 210 have the roughness 230-a. Based on roughening the portions of the surfaces 210 corresponding to the pattern 405-a, the mask 410 may be removed and the surfaces may be cleaned.

As another illustrative example and with reference to the processing step 501, the portions of the surfaces 210 corresponding to the pattern 405-b (e.g., star pattern) may be etched, such that the patterned portions of the surfaces 210 have the roughness 230-b and the unpatterned portions of the surfaces 210 have the roughness 230-a. Based on roughening the portions of the surfaces 210 corresponding to the pattern 405-b, the mask 410 may be removed and the surfaces 210 may be cleaned.

As another illustrative example and with reference to the processing step 502, the portions of the surfaces 210 corresponding to the pattern 405-c (e.g., combination of the star and radial pattern) may be etched, such that the patterned portions of the surfaces 210 have the roughness 230-b and the unpatterned portions of the surfaces 210 have the roughness 230-a. Based on roughening the portions of the surfaces 210 corresponding to the pattern 405-c, the mask 410 may be removed and the surfaces may be cleaned.

Accordingly, the surface 210-a, with the patterned portions roughened to the roughness 230-b and the remaining (e.g., unpatterned) portion having the roughness 230-a, and the surface 210-b, with the patterned portions roughened to the roughness 230-b and the remaining (e.g., unpatterned) portion having the roughness 230-a, may be bonded together according to the techniques described herein with reference to FIG. 2A. For example, a pressure may be applied to a center of the surface 215-a, or the surface 215-b, thereby causing the center of the surfaces 210 to couple together. Accordingly, due to the attraction between the dielectric material 305 deposited on the surfaces 210, one or more segments 220 extending from the center of the surfaces 210 may couple together, causing the bond wave 225.

As described herein, by having a roughness 230-b on the patterned portions (e.g., rough portions) of the surfaces 210 and a roughness 230-a on the unpatterned portions (e.g., smooth portions), the bond wave 225 may be altered to have a relatively decreased amount of distortion and impact from the manufacturing equipment, thereby producing a constant velocity in each direction. As such, the roughening of the surfaces 210 may reduce reliance on precision equipment during the bonding process, may be tailored to each semiconductor 205 (based on the characteristics of the semiconductor 205) to create a constant velocity of the bond wave 225, and enable better edge control to reduce voiding.

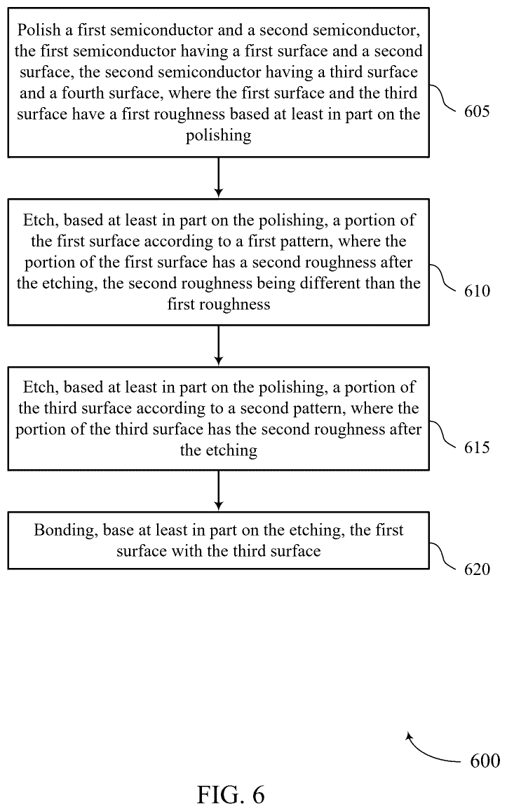

FIG. 6 shows a flowchart illustrating a method 600 that supports techniques for surface modifications during bonding procedures in accordance with examples as disclosed herein. The operations of method 600 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 605, the method may include polishing a first semiconductor and a second semiconductor, the first semiconductor having a first surface and a second surface, the second semiconductor having a third surface and a fourth surface, where the first surface and the third surface have a first roughness based at least in part on the polishing.

At 610, the method may include etching, based at least in part on the polishing, a portion of the first surface according to a first pattern, where the portion of the first surface has a second roughness after the etching, the second roughness being different than the first roughness.

At 615, the method may include etching, based at least in part on the polishing, a portion of the third surface according to a second pattern, where the portion of the third surface has the second roughness after the etching.

At 620, the method may include bonding, based at least in part on the etching, the first surface with the third surface.

In some examples, an apparatus (e.g., a manufacturing system) as described herein may perform a method or methods, such as the method 600. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:
Aspect 1: A method or apparatus including operations, features, circuitry, logic, means, or instructions, or any combination thereof for polishing a first semiconductor and a second semiconductor, the first semiconductor having a first surface and a second surface, the second semiconductor having a third surface and a fourth surface, where the first surface and the third surface have a first roughness based at least in part on the polishing; etching, based at least in part on the polishing, a portion of the first surface according to a first pattern, where the portion of the first surface has a second roughness after the etching, the second roughness being different than the first roughness; etching, based at least in part on the polishing, a portion of the third surface according to a second pattern, where the portion of the third surface has the second roughness after the etching; and bonding, based at least in part on the etching, the first surface with the third surface.
Aspect 2: The method or apparatus of aspect 1, where bonding the first surface and the third surface includes operations, features, circuitry, logic, means, or instructions, or any combination thereof for applying pressure to a segment of the second surface and a segment of the third surface to cause the segment of the first surface and the segment of the third surface to couple; where applying the pressure further causes one or more additional segments of the first surface and one or more additional segments of the third surface to couple; and where the coupling of the one or more additional segments of the first surface and the one or more additional segments of the third surface includes a bond wave.
Aspect 3: The method or apparatus of aspect 2, where a velocity of the bond wave coupling the portion of the first surface and the portion of the third surface is less than a velocity of the bond wave coupling a remaining portion of the first surface and a remaining portion of the third surface, the remaining portion of the first surface and the remaining portion of the third surface having the first roughness.
Aspect 4: The method or apparatus of any of aspects 1 through 3, further including operations, features, circuitry, logic, means, or instructions, or any combination thereof for applying a dielectric material over the first surface and the third surface, where the polishing is based at least in part on applying the dielectric material over the first surface and the third surface.
Aspect 5: The method or apparatus of any of aspects 1 through 4, further including operations, features, circuitry, logic, means, or instructions, or any combination thereof for masking the first surface with a first material according to the first pattern, where etching the portion of the first surface is based at least in part on masking the first surface with the first material and masking the third surface with the first material according to the second pattern, where etching the portion of the third surface is based at least in part on masking the third surface with the first material.
Aspect 6: The method or apparatus of aspect 5, further including operations, features, circuitry, logic, means, or instructions, or any combination thereof for removing, based at least in part on the etching, the first material from the first surface of and the third surface, where bonding the first surface with the third surface is based at least in part on removing the first material.
Aspect 7: The method or apparatus of any of aspects 1 through 6, further including operations, features, circuitry, logic, means, or instructions, or any combination thereof for performing a cleaning procedure on the first surface and the third surface, where bonding the first surface with the third surface is based at least in part on performing the cleaning procedure.
Aspect 8: The method or apparatus of any of aspects 1 through 7, where the polishing includes a chemical-mechanical polishing (CMP) procedure.
Aspect 9: The method or apparatus of any of aspects 1 through 8, where the second roughness is greater than the first roughness.
Aspect 10: The method or apparatus of any of aspects 1 through 9, where the first pattern and the second pattern include a same pattern.
Aspect 11: The method or apparatus of any of aspects 1 through 10, where the first pattern is different from the second pattern.
Aspect 12: The method or apparatus of any of aspects 1 through 11, where the first pattern, the second pattern, or both include one of a star pattern, a radial pattern, a combination of the star pattern and the radial pattern, a square pattern, a triangular pattern, or any combination thereof.
Aspect 13: The method or apparatus of any of aspects 1 through 12, where the first pattern, the second pattern, or both, include a symmetrical pattern or an asymmetrical pattern.
Aspect 14: The method or apparatus of any of aspects 1 through 13, where etching the portion of the first surface and etching the portion of the third surface is in accordance with a low power laser etching procedure.
Aspect 15: The method or apparatus of any of aspects 1 through 14, where etching the portion of the first surface and etching the portion of the third surface is in accordance with a wet etching procedure, a sand blasting procedure, an ice blasting procedure, an implanting procedure, or a plasma etching procedure.
Aspect 16: The method or apparatus of any of aspects 1 through 15, where the first semiconductor and the second semiconductor include respective wafers.
Aspect 17: The method or apparatus of any of aspects 1 through 16, where the first semiconductor and the second semiconductor include respective memory dies.
Aspect 18: The method or apparatus of any of aspects 1 through 17, where the first semiconductor includes a wafer and the second semiconductor includes a memory die.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:
Aspect 19: An apparatus, including: a first semiconductor including a first surface and a second surface; and a second semiconductor including a third surface and a fourth surface, the first surface being bonded with the third surface, where the first surface has a first portion with a first roughness and a second portion with a second roughness, and where the third surface has a first portion with the first roughness and a second portion with the second roughness, the second roughness being different than the first roughness.
Aspect 20: The apparatus of aspect 19, where the second portion of the first surface includes a first pattern, and the second portion of the third surface includes a second pattern.
Aspect 21: The apparatus of any of aspects 19 through 20, where the second portion of the first surface and the second portion of the third surface include a same pattern.
Aspect 22: The apparatus of any of aspects 19 through 21, where the second roughness is greater than the first roughness.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial materials of semiconductor materials on another substrate. The conductivity of the substrate, or sub-regions of the substrate, may be controlled through doping using various chemical species including, but not limited to, phosphorous, boron, or arsenic.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method of manufacturing, comprising:
polishing a first semiconductor and a second semiconductor, the first semiconductor having a first surface and a second surface, the second semiconductor having a third surface and a fourth surface, wherein the first surface and the third surface have a first roughness based at least in part on the polishing;
etching, based at least in part on the polishing, a portion of the first surface according to a first pattern, wherein the portion of the first surface has a second roughness after the etching, the second roughness being different than the first roughness;
etching, based at least in part on the polishing, a portion of the third surface according to a second pattern, wherein the portion of the third surface has the second roughness after the etching; and
bonding, based at least in part on the etching, the first surface with the third surface.

2. The method of claim 1, wherein bonding the first surface and the third surface comprises:
applying pressure to a segment of the second surface and a segment of the fourth surface to cause the segment of the first surface and the segment of the third surface to couple,
wherein applying the pressure further causes one or more additional segments of the first surface and one or more additional segments of the third surface to couple, and
wherein the coupling of the one or more additional segments of the first surface and the one or more additional segments of the third surface comprises a bond wave.

3. The method of claim 2, wherein a velocity of the bond wave coupling the portion of the first surface and the portion of the third surface is less than a velocity of the bond wave coupling a remaining portion of the first surface and a remaining portion of the third surface, the remaining portion of the first surface and the remaining portion of the third surface having the first roughness.

4. The method of claim 1, further comprising:
applying a dielectric material over the first surface and the third surface, wherein the polishing is based at least in part on applying the dielectric material over the first surface and the third surface.

5. The method of claim 1, further comprising:
masking the first surface with a first material according to the first pattern, wherein etching the portion of the first surface is based at least in part on masking the first surface with the first material; and
masking the third surface with the first material according to the second pattern, wherein etching the portion of the third surface is based at least in part on masking the third surface with the first material.

6. The method of claim 5, further comprising:
removing, based at least in part on the etching, the first material from the first surface of and the third surface, wherein bonding the first surface with the third surface is based at least in part on removing the first material.

7. The method of claim 1, further comprising:
performing a cleaning procedure on the first surface and the third surface, wherein bonding the first surface with the third surface is based at least in part on performing the cleaning procedure.

8. The method of claim 1, wherein the polishing comprises a chemical-mechanical polishing (CMP) procedure.

9. The method of claim 1, wherein the second roughness is greater than the first roughness.

10. The method of claim 1, wherein the first pattern and the second pattern comprise a same pattern.

11. The method of claim 1, wherein the first pattern is different from the second pattern.

12. The method of claim 1, wherein the first pattern, the second pattern, or both comprise one of a star pattern, a radial pattern, a combination of the star pattern and the radial pattern, a square pattern, a triangular pattern, or any combination thereof.

13. The method of claim 1, wherein the first pattern, the second pattern, or both, comprise a symmetrical pattern or an asymmetrical pattern.

14. The method of claim 1, wherein etching the portion of the first surface and etching the portion of the third surface is in accordance with a low power laser etching procedure.

15. The method of claim 1, wherein etching the portion of the first surface and etching the portion of the third surface is in accordance with a wet etching procedure, a sand blasting procedure, an ice blasting procedure, an implanting procedure, or a plasma etching procedure.

16. The method of claim 1, wherein the first semiconductor and the second semiconductor comprise respective wafers.

17. The method of claim 1, wherein the first semiconductor and the second semiconductor comprise respective memory dies.

18. The method of claim 1, wherein the first semiconductor comprises a wafer and the second semiconductor comprises a memory die.

19. An apparatus, comprising:
a first semiconductor comprising a first surface and a second surface; and
a second semiconductor comprising a third surface and a fourth surface, the first surface being bonded with the third surface, wherein the first surface has a first portion with a first roughness and a second portion with a second roughness, and wherein the third surface has a first portion with the first roughness and a second portion with the second roughness, the second roughness being different than the first roughness.

20. The apparatus of claim 19, wherein the second portion of the first surface comprises a first pattern, and the second portion of the third surface comprises a second pattern.

21. The apparatus of claim 19, wherein the second portion of the first surface and the second portion of the third surface comprise a same pattern.

22. The apparatus of claim 19, wherein the second roughness is greater than the first roughness.

23. A product formed by a process of:
polishing a first semiconductor and a second semiconductor, the first semiconductor having a first surface and a second surface, the second semiconductor having a third surface and a fourth surface, wherein the first surface and the third surface have a first roughness based at least in part on the polishing;
etching, based at least in part on the polishing, a portion of the first surface according to a first pattern, wherein the portion of the first surface has a second roughness, the second roughness being different than the first roughness;
etching, based at least in part on the polishing, a portion of the third surface according to a second pattern, wherein the portion of the third surface has the second roughness; and
bonding, based at least in part on the etching, the first surface with the third surface.
